(19) United States
(12) Patent Application Publication
(10) Pub. No.: US 2024/0348218 A1
(43) Pub. Date: Oct. 17, 2024

(54) DUAL FEEDBACK CONTINUOUS TIME LINEAR EQUALIZER

(71) Applicant: Intel Corporation, Santa Clara, CA (US)

(72) Inventor: Saurabh ANMADWAR, Nagpur (IN)

(21) Appl. No.: 18/301,280

(22) Filed: Apr. 17, 2023

(51) Int. Cl. H03F 3/45

(52) U.S. Cl. CPC H03F 3/45475; H03F 3/45488

(57) ABSTRACT

An amplifier circuit, comprising an amplification stage, is configured to amplify an input signal, and to generate an output signal as the amplified input signal; a first feedback stage, configured to generate a first feedback voltage based on a voltage of the input signal, and to modify the output signal by the first feedback voltage; and a second feedback stage, configured to generate a second feedback voltage based on a current generated in response to the input signal, and to modify the output signal using the second feedback voltage.

### TECHNICAL FIELD

Various aspects of this disclosure generally relate to a continuation time linear equalizer (CTLE) with two feedback stages.

### BACKGROUND

A CTLE transfer function is ideally the inverse of the channel response. To cancel the intersymbol interference (ISI), the CTLE transfer function must also have sufficient peaking at the Nyquist frequency to best fit the channel's inverse profile. Traditionally, peaking has primarily been achieved using direct current (DC) attenuation, e.g. a source degeneration CTLE. Due to low peaking at the Nyquist frequency, however, this strategy results in smaller eye opening and therefore requires one or more additional gain stages.

Source degeneration stages, which are first order CTLEs, lack a sharp gain profile for higher frequency bands. There are other higher order CTLE topologies to better fit the inverse channel response. These include multi-stage CTLEs and Q-shaping CTLEs. Other alternate approaches include subtraction/multipath based CTLE, which has band specific equalization. Although these approaches provide greater peaking at the Nyquist frequency, they are either limited by power or linearity issues. Alternatively, sufficient peaking can be achieved with an inductor (e.g. exhibiting an inductance of only a few nH), but this comes with expense of a very large area, which may render it undesirable.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIGS. 1A and 1B depict a known CTLE and a signal-flow diagram of the known CTLE, respectively;

FIGS. 2A and 2B depict a known Q-shaping CTLE and a signal flow diagram of the Q-shaping CTLE, respectively;

FIGS. 3A and 3B depict a CTLE according to a first aspect of the disclosure and a signal diagram of this CTLE, respectively;

FIG. 4 depicts a CTLE circuit according to second aspect of the disclosure;

FIG. 5 depicts simulation results;

FIG. 6 depicts a CTLE according to a third aspect of the disclosure; and

FIG. 7 depicts a CTLE including a triode biased PMOS and common mode feedback loop.

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D XPointTM, among others, or any combination thereof. Registers, shift registers, processor registers, data buffers, among others, are also embraced herein by the term memory. The term “software” refers to any type of executable instruction, including firmware.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

A CTLE may be used to linearly amplify a range of frequencies in a signal. As a CTLE performs an amplification function, it may be referred to herein simply as an amplifier. Any reference to an amplifier is intended to include the CTLEs as disclosed herein, such as according to the first aspect of the disclosure, the second aspect of the disclosure, or the third aspect of the disclosure.

As described above, previous efforts at creating a CTLE have included source degeneration based multi-stage CTLE; however, this has resulted in limited or insufficient peaking, as well as a slope of less than 20 dB/dec. Other such efforts have included a passive inductor-based Q-Shaping CTLE; however, the necessary inductor due to the high Q requirement is expensive and exhibits poor linearity. Still other such efforts have included a multi-path CTLE for multiple pole-zero pairs on the datapath overall transfer function; however, this has resulted in additional power and loading effects with use of the multi-path and complexity in adaptation. Finally, other efforts have included adding additional taps in the Decision-Feedback Equalizer (DFE) or the Feed-Forward Equalizer (FFE) to cancel the long tail residual ISI due to the low frequency ISI; however, this increases layout complexity and power requirements.

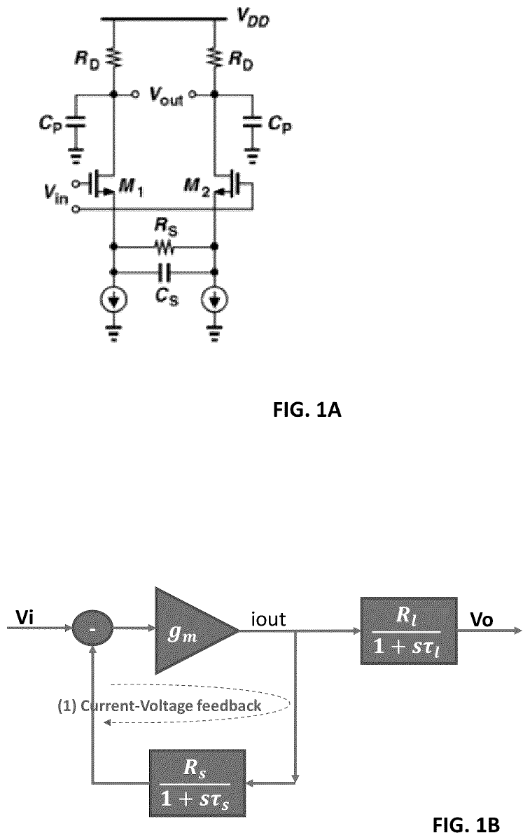

FIG. 1A depicts a known CTLE, and FIG. 1B depicts a signal-flow diagram of the CTLE depicted in FIG. 1A. As can be seen in FIG. 1B, the CTLE of FIG. 1A includes a single current-voltage feedback stage to generate a feedback voltage.

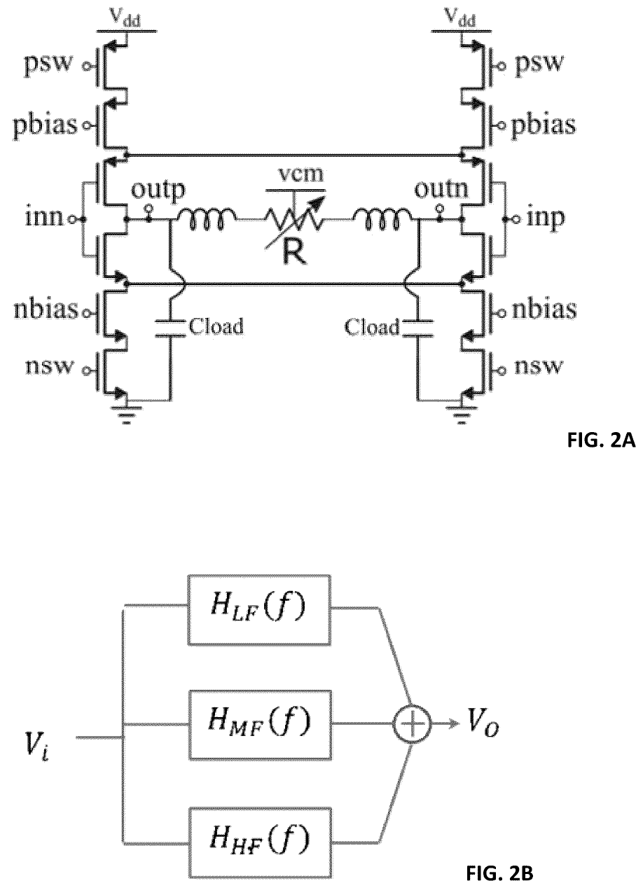

FIG. 2A depicts a known Q-shaping CTLE, and FIG. 2B depicts a signal flow diagram of the Q-shaping CTLE of FIG. 2A.

The CTLE described herein includes two feedback stages (e.g. dual feedback), with which an improved peaking profile for higher eye height due to higher gain at the Nyquist frequency can be achieved, without the need for an inductor, and with improved linearity compared to solutions with an inductor.

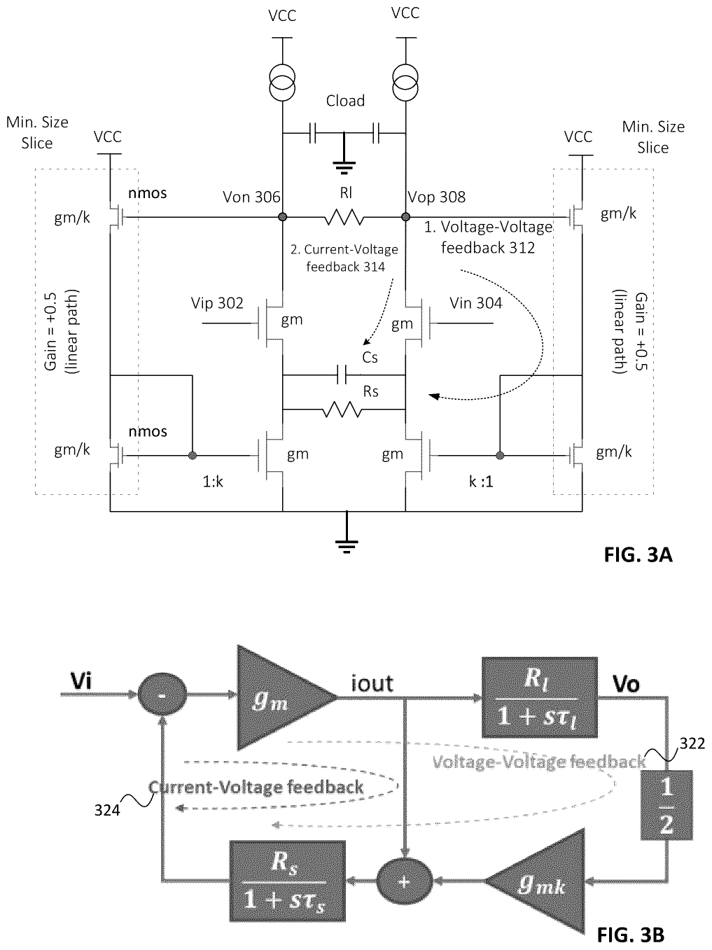

FIG. 3A depicts a CTLE according to an aspect of the disclosure. This CTLE includes a positive input 302, a negative input 304, a positive output 306, and a negative output 308. The CTLE includes a first feedback stage 312, and a second feedback stage 314.

FIG. 3B depicts a signal diagram of the CTLE of FIG. 3A, including a first feedback stage exhibiting a voltage-voltage feedback 322, and a second feedback stage exhibiting a current-voltage feedback 324.

The CTLE of FIGS. 3A or 3B may mimic a Q-shaping CTLE equalization profile, and as such, it may result in improved height (EH) and signal to noise ratio (SNR) for a more power efficient receiver analog front end (Rx-AFE) design. In some configurations, the improved EH may be up to, or even exceed, four times that of the CTLE in FIG. 1A.

The CTLE in FIGS. 3A and 3B may include two overlapping feedback stages/paths. The first feedback stage 312 may include a voltage-to-voltage feedback. The second feedback stage 314 may include a current-to-voltage feedback. That is, this second feedback stage may be, or function similar to, a current-to-voltage feedback stage, for example such as the current-to-voltage feedback stage as shown in FIG. 2A. These two feedback paths may be modelled as shown in FIG. 3B, in which the two feedback paths result in transfer function H(s). Similar to a passive inductor-based Q-shaping CTLE, the transfer function has one-zero and a complex pole pair, resulting in improved peaking and bandwidth enhancement. According to an aspect of the disclosure, the transfer function may be stated as follows:

$$H ( s ) = \frac{{V}_{o}}{{V}_{in}} = \frac{- {g}_{m} {R}_{l} ( 1 + s {τ}_{s} )}{[ 1 + {g}_{m} {R}_{s} + \frac{{g}_{m} {g}_{m} {R}_{s} {R}_{l}}{2} ] + s [ {τ}_{s} + {τ}_{l} ( 1 + {g}_{m} {R}_{s} ) ] + {s}^{2} {τ}_{s} {τ}_{l}} \qquad ( 1 )$$

Compared to a source degeneration based CTLE, the topology disclosed herein (for example, as depicted in FIG. 3A) reuses the current sources for implementation of the second feedback. This efficient implementation of two feedbacks to obtain a tunable complex pole pair results in higher gain-bandwidth and linearity (e.g. higher EH).

This CTLE may be operated in two modes, as follows: (1) Normal Mode, in which only the DC is attenuated, and with varying source resistance (Rₛ); or a Q-shaping mode, in which DC is attenuated and peak gain is amplified (EH=2×<normal mode>).

The CTLE circuits disclosed herein offer multiple advantages, including, but not limited to, the following. First, they permit single stage higher gain-bandwidth EQ (equalization) profiling without an inductor, compared to known methods. Second, they result in greater linearity, since the circuit effectively has stronger negative feedback. Third, they offer a greater boost range for a given source resistance sweep. Fourth, this has ˜15 dB higher CMRR compared to known methods, due to inherent voltage-voltage feedback path). Therefore, usage of this CTLE topology improves the efficiency of the receiver analog-front-end (AFE), since it can reduce the performance requirements on the subsequent stages of the AFE.

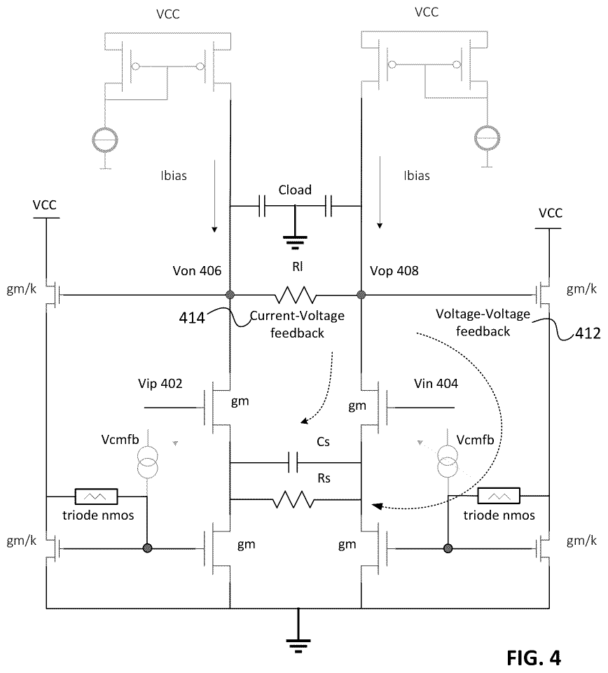

FIG. 4 depicts a CTLE circuit according to second aspect of the disclosure. This CTLE in FIG. 4 is an inductorless dual-feedback CTLE with a common mode control mechanism (e.g. it includes a scheme to calibrate an output common mode). This CTLE circuit includes a positive input 402, a negative input 404, a positive output 406, and a negative output 408. The CTLE circuit includes a first feedback stage 412, providing voltage-voltage feedback, and a second feedback stage 414, providing current-voltage feedback. The first feedback stage 412 is highly linear, as it is a buffer with gm-by-gm ratio and is of minimal size that results in insignificant power and loading on the main stage. Additionally, the Miller Effect significantly reduces the gate-source capacitance of the main feedback device.

The normal mode, which mainly affects DC attenuation, is more useful for low-loss to medium-loss channels. This is achieved by varying source resistance (Rₛ) because of lower peak gain. However, the Q-shaping mode, which provides very high peak gain, is mostly suitable for medium to long channels. This is achieved by keeping Rₗ=R_{const}+2Rₛ and varying (Rₛ). Increasing Rₗ linearly along with Rₛ increases the effective Q of the circuit which increases peak gain at the Nyquist frequency. The critical damping condition i.e., Q=0.5 is met by

$${R}_{l} = \frac{{R}_{s}}{2} ,$$

which can be obtained from following equation:

$$Q = 0.5 \frac{\sqrt{1 + {A}_{ol , 1} + {A}_{ol , 2}}}{1 + \frac{{A}_{ol , 1}}{2}} \\ where {A}_{ol 1} = {g}_{m} {R}_{s} \&\& {A}_{ol 2} = \frac{{g}_{m} {R}_{s} {g}_{mk} {R}_{l}}{2} \qquad ( 2 )$$

Open loop gain by itself is not instable (e.g. does not exhibit stability problems) since it has an inherent lag-lead compensation. In other words, source degeneration feedback always remains the fastest feedback path, thereby keeping the circuit unconditionally stable. The worst-case phase margin seen in the stability analysis in Q-shaping mode is 65 deg.

$${A}_{open \_ loop} = \frac{{g}_{m} {R}_{s}}{1 + s {τ}_{s}} [ \frac{( 1 + s {τ}_{l} ) + 0.5 {R}_{l} {g}_{m}}{( 1 + s {τ}_{l} )} ] \qquad ( 3 )$$

Although the feedback path consumes 6% additional power compared to the source-degeneration core, higher eye-height provided due to better peak gain and linearity effectively results in better current efficiency and much better SNR (Table 1). Also, due to sufficient eye opening at CTLE stage itself, following gain stages in AFE can be operated with lower power due to relaxed gain requirements. Therefore, usage of this CTLE can result in a very power- and area-efficient Rx design.

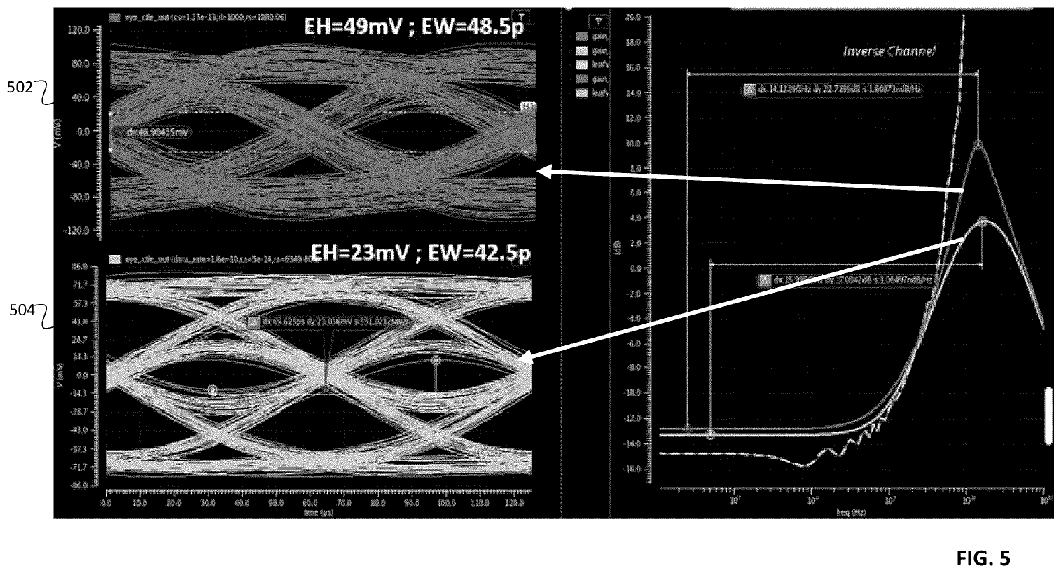

FIG. 5 depicts simulation results comparing eye-diagrams of the CTLE disclosed herein 502 with that of a conventional CTLE relying on source degeneration 504. The channel shows attenuation of ˜19 dB@8 GHz, assuming 1 pF padcap at Rx input. Data is applied for PRBS9 @16 Gbps with 1.3 dB boost from Tx FFE and a swing of 600mVppdiff at the channel input. Results are based on a post layout netlist of the half-cell and are simulated across 5 basic corners. FIG. 5 shows that the best eye opening with the proposed CTLE according to this disclosure has roughly twice the height of a source degeneration based CTLE.

With respect to the Q-shaping mode, the eye opening is four times as great as that of the conventional CTLE, that is, twice the normal mode. The passive inductor-based Q-shaping CTLE requires a large inductor of approximately ˜20 nH for these datarates. In both modes of the proposed CTLE, the optimal boost is ˜22 dB. However, with Q-shaping, a higher peak gain, and therefore larger eye opening, can be obtained. Considering this, the SNR along with other comparison parameters are depicted in table 1 below.

| | | | Q-shaping | | |
|---|---|---|---|---|---|
| | | Disclosed | 20 nH | Source | |
| Parameters | Condition | CTLE | inductor | Degeneration | Unit |
| CMRR@1 MHz | With 40 dB | 58 | 42 | 43 | dB |
| | CMFB loop | | | | |
| | gain | | | | |
| Linearily | 1 dB | 350 | 100 | 235 | mVdiff |
| | compression | | | | |
| | pt. o/p | | | | |
| | referred | | | | |
| Eye height | Normal/Q- | 52/96 | 75 | 23 | mV |
| (EH) | shaping mode | | | | |
| SNR | Normal/Q- | 24.4/44.5 | 29.4 | 12.5 | V/Vrms |
| (EH/Noise) | shaping mode | | | | |
| EH/Ivcc | Current usage | 23/42.5 | 35.5 | 11 | V/A |
| | efficiency | | | | |

The CTLE as disclosed herein burns ˜2 mW of power assuming 25 fF load cap.

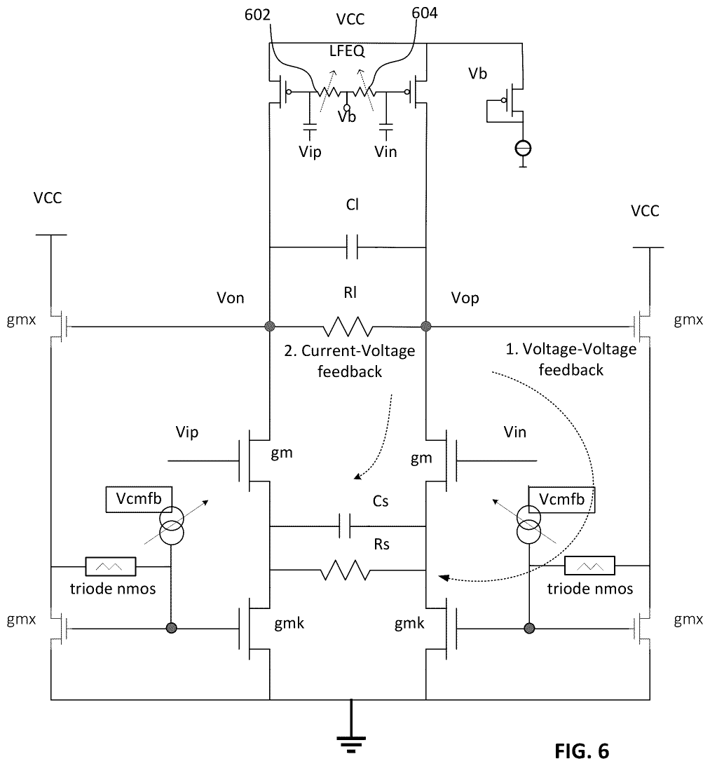

According to a third aspect of the disclosure, the CTLE may be optionally configured as depicted in FIG. 6. The CTLE according to the third aspect includes the first feedback stage and the second feedback stage as with the CTLE of the first aspect and the second aspect, but it also includes, inter alia, two feed-forward ohmic resistors 602 and 604 in a feed-forward stage. This configuration enhances the unity gain bandwidth (UGB) of the main stage, as well as leverages forward coupling to the top p-type metal-oxide semiconductor (PMOS) gate for low frequency equalization (LFEQ). Tuning the feed-forwarding resistor on the gate of these PMOS current sources, affects only mid frequencies without impacting gain at dc as well as peak frequency i.e., high frequency boost is fixed.

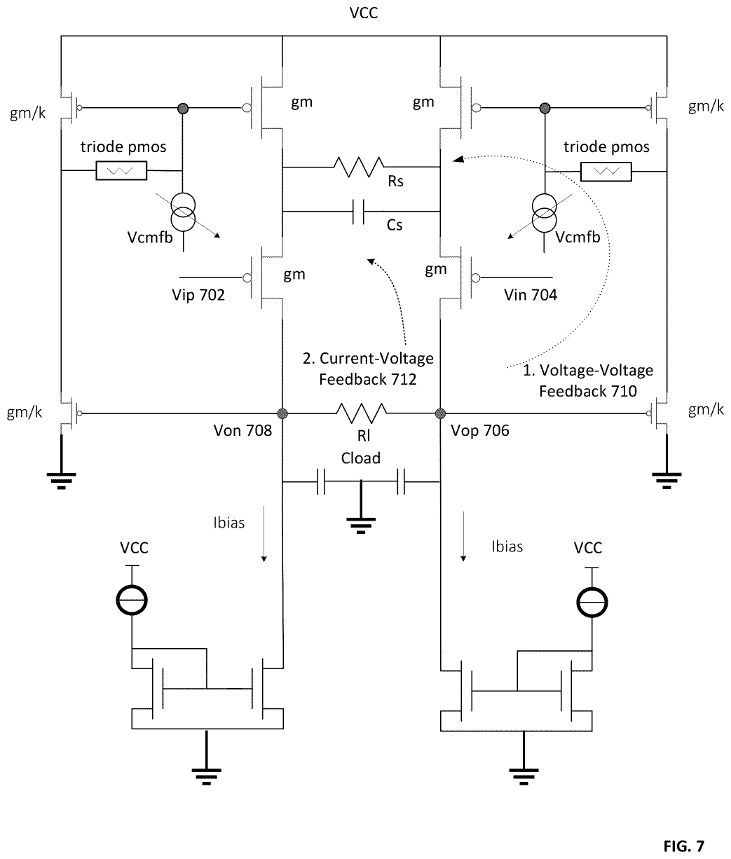

FIG. 7 depicts a CTLE that includes a p-channel metal oxide semiconductor (PMOS) circuit, according to a fourth aspect of the disclosure. As with the other aspects, the CTLE includes a positive input terminal 702, a negative input terminal 704, a positive output terminal 706, and a negative output terminal 708. The CLTE further includes a first feedback stage 710, configured to provide a voltage-voltage feedback, and a second feedback stage 712, configured to provide a current-voltage feedback. Both the positive and negative paths include a common mode feedback loop that includes PMOS that baised in triode, which results in increased stability by attenuating or canceling dynamic common mode perturbations.

In an optional configuration, the amplifier circuit may be configured as part of a system on chip (SOC). The SOC may include any device that itself includes functionality to wirelessly receive data. This functionality may optionally include an ability to receive wireless signals in millimeter wavelengths.

In another optional configuration, the amplifier circuit may be configured as part of a wireless receiver. In this manner, the wireless receiver may be configured to receive wireless signals, such as optionally in the millimeter wavelengths. The wireless receiver may be configured to perform one or more equalization functions on a received signal, such as by using the amplifier circuit as described herein. The one or more equalization functions may include continuous time linear equalization.

In another optional configuration, the amplifier circuit may be configured as part of a user device. The user device may be or include a smartphone, a tablet computer, a laptop, a wearable device, or any of these. The user device may include a receiver for receiving wireless signals, which may optionally be in the millimeter wavelengths. The user device may be configured to perform one or more equalization functions on the received wireless signals, such as one or more continuous time linear equalization functions.

In another optional configuration, the amplifier circuit may be configured as part of a vehicle. The vehicle may include a receiver for receiving wireless signals, which may optionally be in the millimeter wavelengths. The vehicle (e.g. a receiver of the vehicle) may be configured to perform one or more equalization functions on the received wireless signals, such as one or more continuous time linear equalization functions.

Further aspects of the disclosure will be demonstrated by way of example:

In Example 1, an amplifier circuit, comprising an amplification stage, configured to amplify an input signal, and to generate an output signal as the amplified input signal; a first feedback stage, configured to generate a first feedback voltage based on a voltage of the input signal, and to modify the output signal by the first feedback voltage; and a second feedback stage, configured to generate a second feedback voltage based on a current generated in response to the input signal, and to modify the output signal using the second feedback voltage.

In Example 2, the amplifier circuit of Example 1, wherein the first feedback stage is configured to determine the first feedback voltage based, at least in part, on the second feedback voltage.

In Example 3, the amplifier circuit of Example 1 or 2, wherein the first feedback stage comprises a first transistor, comprising a first gate, a first drain, and a first source; wherein the first gate is electrically connected to a terminal for the output signal; and wherein the first source is electrically conductively connected to a reference voltage.

In Example 4, the amplifier circuit of Example 3, wherein the first feedback stage further comprises a second transistor, comprising a second gate, a second drain, and a second source; and wherein the first drain is electrically conductively connected to the second gate and the second source.

In Example 5, the amplifier circuit of any one of Examples 1 to 4, wherein the second feedback stage comprises a third transistor, comprising a third gate, a third drain, and a third source; wherein the third gate is electrically connected to a terminal for the output signal; and wherein the third source is electrically connected to a reference voltage.

In Example 6, the amplifier circuit of Example 5, wherein the feedback stage further comprises a fourth transistor, comprising a fourth gate, a fourth drain, and a fourth source; and wherein the third drain is electrically connected to the fourth gate and the fourth drain.

In Example 7, the amplifier circuit of any one of Examples 1 to 6, wherein the input signal is a differential input signal comprising a positive input signal portion and a negative input signal portion; and wherein the output signal is a differential input signal comprising a positive output signal portion and a negative output signal portion; wherein the continuation time linear equalizer further comprises: a first input terminal, configured to receive the positive input signal; a second input terminal, configured to receive the negative input signal; a first output terminal, configured to output the positive output signal; and a second output terminal, configured to output the negative output signal.

In Example 8, the amplifier circuit of Example 7, further comprising a fifth transistor, comprising a fifth gate, a fifth drain, and a fifth source; and a sixth transistor, comprising a sixth gate, a sixth drain, and a sixth source; wherein a terminal for the positive input signal is electrically conductively connected to the fifth gate; wherein a terminal for the negative input signal is electrically conductively connected to the sixth gate; wherein a terminal for the positive output signal is electrically conductively connected to the fifth drain or the fifth source; and wherein a terminal for the negative output signal is electrically conductively connected to the sixth drain or the sixth source.

In Example 9, the amplifier circuit of any one of Examples 3 to 8, further comprising an N-type metal oxide transistor, connected on one end between either the first drain or the first source and either the second drain or the second source, and on another end to the fourth gate, and configured to operate in a triode region.

In Example 10, the amplifier circuit of any one of Examples 1 to 9, wherein the amplifier circuit is configured as a continuous time linear equalizer.

In Example 11, an amplifier circuit, comprising: an amplification means for amplifying an input signal and generating an output signal as the amplified input signal; and a first feedback means for generating a first feedback voltage based on a voltage of the input signal, and modifying the output signal by the first feedback voltage; and a second feedback means, for generating a second feedback voltage based on a current generated in response to the input signal, and to modify the output signal using the second feedback voltage.

In Example 12, the amplifier circuit of Example 11, wherein the first feedback means comprises a first switching means, comprising a first gate, a first drain, and a first source; wherein the first gate is electrically connected to a terminal for the output signal; and wherein one of the first source or the first drain is electrically conductively connected to a reference voltage.

In Example 13, the amplifier circuit of Example 12, wherein the first feedback means further comprises a second switching means, comprising a second gate, a second drain, and a second source; and wherein the first source or the first drain that is not electrically conductively connected to the reference voltage is electrically conductively connected to the second gate and one of the second source or the second drain.

In Example 14, the amplifier circuit of any one of Example 11 to 13, wherein the second feedback means comprises a third switching means, comprising a third gate, a third drain, and a third source; wherein the third gate is electrically connected to a terminal for the output signal; and wherein at least one of the third source or the third drain is electrically connected to a reference voltage.

In Example 15, the amplifier circuit of Example 14, wherein the first feedback means further comprises a fourth switching means, comprising a fourth gate, a fourth drain, and a fourth source; and wherein the third source or the third drain that is not electrically connected to the reference voltage is electrically connected to the fourth gate and at least one of the fourth source or the fourth drain.

In Example 16, the amplifier circuit of any one of Examples 11 to 15, wherein the input signal is a differential input signal comprising a positive input signal portion and a negative input signal portion; and wherein the output signal is a differential input signal comprising a positive output signal portion and a negative output signal portion; wherein the continuation time linear equalizer further comprises: a first input terminal, configured to receive the positive input signal; a second input terminal, configured to receive the negative input signal; a first output terminal, configured to output the positive output signal; and a second output terminal, configured to output the negative output signal.

In Example 17, the amplifier circuit of Example 16, further comprising a fifth switching means, comprising a fifth gate, a fifth drain, and a fifth source; and a sixth switching means, comprising a sixth gate, a sixth drain, and a sixth source; wherein a terminal for the positive input signal is electrically conductively connected to the fifth gate; wherein a terminal for the negative input signal is electrically conductively connected to the sixth gate; wherein a terminal for the positive output signal is electrically conductively connected to the fifth drain or the fifth source; and wherein a terminal for the negative output signal is electrically conductively connected to the sixth drain or the sixth source.

In Example 18, the amplifier circuit of any one of Examples 13 to 17, further comprising an N-type metal oxide transistor, connected on one end between either the first drain or the first source and either the second drain or the second source, and on another end to the fourth gate, and configured to operate in a triode region.

In Example 19, a method of continuous time linear equalizing, comprising: amplifying an input signal and generating an output signal as the amplified input signal; generating a first feedback voltage based on a voltage of the input signal and modifying the output signal by the first feedback voltage; and generating a second feedback voltage based on a current of the input signal and modifying the output signal using the current feedback.

In Example 20, the method of continuous time linear equalizing of Example 19, wherein generating the voltage feedback comprises generating the voltage feedback using a first transistor, comprising a first gate, a first drain, and a first source; wherein the first gate is electrically connected to a terminal for the output signal; and wherein the first source is electrically conductively connected to a reference voltage.

In Example 21, the method of continuous time linear equalizing of Example 20, wherein generating the first feedback voltage further comprises generating the first feedback voltage using a second transistor, comprising a second gate, a second drain, and a second source; and wherein the first drain is electrically conductively connected to the second gate and the second source.

In Example 22, the method of continuous time linear equalizing of Example 19, wherein generating the second feedback voltage comprises generating the second feedback voltage using a third transistor, comprising a third gate, a third drain, and a third source; wherein the third gate is electrically connected to a terminal for the output signal; and wherein the third source is electrically connected to a reference voltage.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. An amplifier circuit, comprising:
an amplification stage, configured to amplify an input signal, and to generate an output signal as the amplified input signal;
a first feedback stage, configured to generate a first feedback voltage based on a voltage of the input signal, and to modify the output signal by the first feedback voltage; and
a second feedback stage, configured to generate a second feedback voltage based on a current generated in response to the input signal, and to modify the output signal using the second feedback voltage.

2. The amplifier circuit of claim 1, wherein the first feedback stage is configured to determine the first feedback voltage based, at least in part, on the second feedback voltage.

3. The amplifier circuit of claim 2, wherein the first feedback stage comprises a first transistor, comprising a first gate, a first drain, and a first source;
wherein the first gate is electrically connected to a terminal for the output signal; and
wherein the first source is electrically conductively connected to a reference voltage.

4. The amplifier circuit of claim 3, wherein the first feedback stage further comprises a second transistor, comprising a second gate, a second drain, and a second source; and
wherein the first drain is electrically conductively connected to the second gate and the second source.

5. The amplifier circuit of claim 1, wherein the second feedback stage comprises a third transistor, comprising a third gate, a third drain, and a third source;
wherein the third gate is electrically connected to a terminal for the output signal; and
wherein the third source is electrically connected to a reference voltage.

6. The amplifier circuit of claim 5, wherein the feedback stage further comprises a fourth transistor, comprising a fourth gate, a fourth drain, and a fourth source; and
wherein the third drain is electrically connected to the fourth gate and the fourth drain.

7. The amplifier circuit of claim 1, wherein the input signal is a differential input signal comprising a positive input signal portion and a negative input signal portion; and
wherein the output signal is a differential input signal comprising a positive output signal portion and a negative output signal portion;
wherein the continuation time linear equalizer further comprises:
a first input terminal, configured to receive the positive input signal;
a second input terminal, configured to receive the negative input signal;
a first output terminal, configured to output the positive output signal; and
a second output terminal, configured to output the negative output signal.

8. The amplifier circuit of claim 7, further comprising a fifth transistor, comprising a fifth gate, a fifth drain, and a fifth source; and a sixth transistor, comprising a sixth gate, a sixth drain, and a sixth source; wherein a terminal for the positive input signal is electrically conductively connected to the fifth gate; wherein a terminal for the negative input signal is electrically conductively connected to the sixth gate; wherein a terminal for the positive output signal is electrically conductively connected to the fifth drain or the fifth source; and wherein a terminal for the negative output signal is electrically conductively connected to the sixth drain or the sixth source.

9. The amplifier circuit of claim 3, further comprising an N-type metal oxide transistor, connected on one end between either the first drain or the first source and either the second drain or the second source, and on another end to the fourth gate, and configured to operate in a triode region.

10. The amplifier circuit of claim 1, wherein the amplifier circuit is configured as a continuous time linear equalizer.

11. A system on chip, comprising the amplifier circuit of claim 1.

12. A wireless receiver, comprising the amplifier circuit of claim 1.

13. A user device, comprising the amplifier circuit of claim 1.

14. A vehicle, comprising the amplifier circuit of claim 1.

15. An amplifier circuit, comprising:
an amplification means for amplifying an input signal and generating an output signal as the amplified input signal; and
a first feedback means for generating a first feedback voltage based on a voltage of the input signal, and modifying the output signal by the first feedback voltage; and
a second feedback means, for generating a second feedback voltage based on a current generated in response to the input signal, and to modify the output signal using the second feedback voltage.

16. The amplifier circuit of claim 15, wherein the first feedback means comprises a first switching means, comprising a first gate, a first drain, and a first source;
wherein the first gate is electrically connected to a terminal for the output signal; and
wherein one of the first source or the first drain is electrically conductively connected to a reference voltage.

17. The amplifier circuit of claim 16, wherein the first feedback means further comprises a second switching means, comprising a second gate, a second drain, and a second source; and
wherein the first source or the first drain that is not electrically conductively connected to the reference voltage is electrically conductively connected to the second gate and one of the second source or the second drain.

18. The amplifier circuit of claim 15, wherein the second feedback means comprises a third switching means, comprising a third gate, a third drain, and a third source;
wherein the third gate is electrically connected to a terminal for the output signal; and
wherein at least one of the third source or the third drain is electrically connected to a reference voltage.

19. A method of continuous time linear equalizing, comprising:
amplifying an input signal and generating an output signal as the amplified input signal;
generating a first feedback voltage based on a voltage of the input signal and modifying the output signal by the first feedback voltage; and
generating a second feedback voltage based on a current of the input signal and modifying the output signal using the current feedback.

20. The method of continuous time linear equalizing of claim 19, wherein generating the voltage feedback comprises generating the voltage feedback using a first transistor, comprising a first gate, a first drain, and a first source;
wherein the first gate is electrically connected to a terminal for the output signal; and
wherein the first source is electrically conductively connected to a reference voltage.
